(19) United States
(12) Patent Application Publication
(10) Pub. No.: US 2006/0284643 A1
(43) Pub. Date: Dec. 21, 2006

(54) Method for inspecting array substrates

(76) Inventors: Mitsuhiro Yamamoto, Fukaya-shi (JP); Masaki Miyatake, Konosu-shi (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(21) Appl. No.: 11/510,629

(22) Filed: Aug. 28, 2006

Related U.S. Application Data
(63) Continuation of application No. PCT/JP05/02816, filed on Feb. 22, 2005.

(30) Foreign Application Priority Data
Mar. 3, 2004 (JP) 2004-059275

(51) Int. Cl. G01R 31/26

(52) U.S. Cl. 324/765

(57) ABSTRACT

A method for inspecting array substrates, which includes a first array substrate having first pads and first electrodes, and a second array substrate having second pads and second electrodes, the method comprising connecting the first pads to terminals formed an array of inspection pad groups and disposed in a predetermined arrangement, bringing probes with an arrangement corresponding to the predetermined arrangement into contact with the terminals, and supplying electric power to the first electrodes via the probes, thereby inspecting whether the first electrodes of the first array substrate is defective or not, and connecting the second pad to the terminals, bringing the probes, without changing the arrangement thereof, into contact with the terminals, and supplying electric power to the second electrodes via the probes, thereby inspecting whether the second electrodes of the second array substrate is defective or not.

### CROSS REFERENCE TO RELATED APPLICATIONS

This is a Continuation Application of PCT Application No. PCT/JP2005/002816, filed Feb. 22, 2005, which was published under PCT Article 21(2) in Japanese.

This application is based upon and claims the benefit of priority from prior Japanese Patent Application No. 2004-059275, filed Mar. 3, 2004, the entire contents of which are incorporated herein by reference.

### BACKGROUND OF THE INVENTION

1. Field of the Invention

The present invention relates to a method for inspecting array substrates.

2. Description of the Related Art

A liquid crystal display device is used in various components such as a display unit of a notebook personal computer (notebook PC), a display unit of a cellular phone, and a display unit of a TV receiver. Thus, depending on uses of liquid crystal display devices, there is a demand for various sizes of liquid crystal display devices, such as 12-inch and 15-inch display devices. This kind of liquid crystal display device includes an array substrate, which has a display area and a non-display area surrounding the display area, an opposite substrate that is arranged opposite to the array substrate, and a liquid crystal layer that is held between the array substrate and the opposite substrate.

In the display area of the array substrate, a plurality of scanning lines and a plurality of signal lines are formed in a matrix, and pixels are formed at intersections of the scanning lines and signal lines. Each of the pixels includes at least one switching element and a pixel electrode that is connected to the switching element. In the non-display area, a scanning line driving circuit and a signal line driving circuit, which drive the pixels, are disposed. By providing the driving circuits on the array substrate, a thin liquid crystal display device can be formed. A plurality of terminals for inputting/outputting signals are provided on one side of the array substrate that is formed as described above. These terminals are connected to the scanning line driving circuit and the signal line driving circuit.

The array substrate is subjected to an inspection step in order to detect a defect in the manufacturing process. In the inspection step, signals are input/output to/from the terminals that are provided on one side of the array substrate, and thus an inspection is executed.

Jpn. Pat. Appln. KOKAI Publication No. 11-271177, Jpn. Pat. Appln. KOKAI Publication No. 2000-3142 and U.S. Pat. No. 5,268,638 disclose techniques relating to inspection methods and inspection apparatuses.

Jpn. Pat. Appln. KOKAI Publication No. 11-271177 discloses a technique having a feature in a dot-defect inspection process in the inspection of an amorphous-type LCD (Liquid Crystal Display) substrate.

This technique makes use of the following phenomenon. Direct light of a DC component is made incident on the entire surface of the LCD substrate, and the amorphous silicon film senses the light and is rendered electrically conductive. By detecting a leak amount of charge that is stored in a storage capacitance, the condition of a defect can be determined. The technique of Jpn. Pat. Appln. KOKAI Publication No. 2000-3142 takes advantage of such a phenomenon that when an electron beam is radiated on a pixel electrode, secondary electrons that are emitted are proportional to a voltage that is applied to a thin-film transistor. The technique of U.S. Pat. No. 5,268,638 also makes use of secondary electrons that are emitted when an electron beam is applied to the pixel electrode.

When liquid crystal display devices of different sizes are formed, array substrates that are included in these liquid crystal display devices have different sizes. There is no uniformity in disposition of plural terminals that are disposed on the array substrates of different sizes. Thus, when the array substrates of different sizes are to be inspected, it is not possible to use the same inspection apparatus. In particular, it is difficult to inspect various array substrates by using probes that are arranged with the same pitch.

The price of a product of a liquid crystal display device is greatly influenced by the cost of the manufacturing equipment. In the manufacturing equipment, the inspection apparatus is indispensable. Needless to say, the inspection apparatus has an influence on the product price.

### BRIEF SUMMARY OF THE INVENTION

The present invention has been made in consideration of the above problems, and an object of the invention is to provide an inspection method for array substrates, which can reduce the cost of an inspection apparatus. Moreover, the inspection method can reduce the number of occasions in which design changes or modifications need to be made for the inspection apparatus, and can suppress an increase in product price of liquid crystal display devices.

According to an aspect of the present invention, there is provided a method for inspecting array substrates, which includes a first array substrate having at an end portion thereof first pads for electric power supply with a first array and first electrodes to be inspected, and a second array substrate having at an end portion thereof second pads for electric power supply with a second array different from the first array and second electrodes to be inspected, the method comprising:

connecting the first pads to terminals formed an array of inspection pad groups and disposed in a predetermined arrangement, bringing probes with an arrangement corresponding to the predetermined arrangement into contact with the terminals, and supplying electric power to the first electrodes via the probes, thereby inspecting whether the first electrodes of the first array substrate is defective or not; and

connecting the second pad to the terminals, bringing the probes, without changing the arrangement thereof, into contact with the terminals, and supplying electric power to the second electrodes via the probes, thereby inspecting whether the second electrodes of the second array substrate is defective or not.

According to another aspect of the present invention, there is provided a method for inspecting array substrates, each of which includes a substrate on which a plurality of scanning lines and a plurality of signal lines are disposed to intersect each other, pixel portions, which are formed on the substrate, arranged close to intersections of the scanning lines and the signal lines and includes switching elements and auxiliary capacitors, and a regular pad group that is provided to supply or output signals to the scanning lines and the signal lines, the method comprising:

forming in advance an inspection pad groups including terminals of an arrangement pattern corresponding to an arrangement pattern of a probe group of a prescribed inspection apparatus on the array substrates even in a case where different kinds of the array substrates, and connecting associated terminals of the regular pad group to the terminals of each of the inspection pad groups via wiring lines; and

bringing, at a time of an inspection, the probe group into contact with the terminals of the inspection pad groups of the array substrates of different kinds, without changing the arrangement pattern of the probe group of the inspection apparatus, thereby inspecting whether the array substrates are defective or not.

Additional advantages of the invention will be set forth in the description which follows, and in part will be obvious from the description, or may be learned by practice of the invention. The advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a view for explaining a presupposed technique of the present invention, that is, an explanatory view showing a basic structure of an amorphous silicon type array substrate;

FIG. 2 is a view for explaining a presupposed technique of the present invention, that is, an explanatory view showing a basic structure of a polysilicon type array substrate;

FIG. 3 is a schematic cross-sectional view of a liquid crystal display panel according to an embodiment of the present invention;

FIG. 4 is a perspective view of a part of the liquid crystal display panel;

FIG. 5 is an explanatory view showing an example of arrangement of array substrates on a mother substrate;

FIG. 6 schematically shows the array substrate according to the embodiment of the invention;

FIG. 7 is a schematic plan view that shows, in enlarged scale, a part of a pixel region of the array substrate shown in FIG. 6;

FIG. 8 is a schematic cross-sectional view of a liquid crystal display panel including the array substrate shown in FIG. 7;

FIG. 9 is a view for explaining the basic structure and operation of an electron beam tester according to the embodiment of the invention;

FIG. 10 is an explanatory view showing a main part of an array substrate according to a first embodiment of the invention;

FIG. 11A schematically shows the structure of a part of an inspection pad array shown in FIG. 10;

FIG. 11B schematically shows the structure of another part of the inspection pad array shown in FIG. 10; and

FIG. 12 is an explanatory view showing a main part of an array substrate according to a second embodiment of the invention.

### DETAILED DESCRIPTION OF THE INVENTION

An inspection method for an array substrate according to an embodiment of the present invention will now be described in detail with reference to the accompanying drawings.

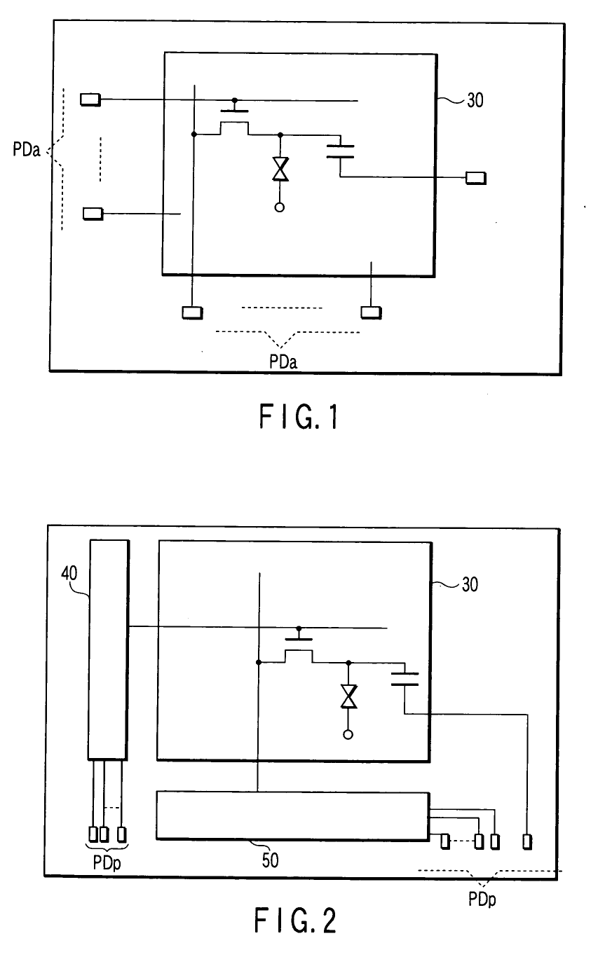

Presupposed techniques of the invention are first described. As is shown in FIG. 1 and FIG. 2, array substrates fall into two types: an amorphous silicon type array substrate and a polysilicon type array substrate. Taking an XGA (extended Graphics Array) as an example, an amorphous silicon type array substrate includes a pixel region 30, and pad groups PDa comprising about 3000 terminals for connection to external circuits. On the other hand, a polysilicon type array substrate includes, in addition to the pixel region 30, a scanning line driving circuit 40 and a signal line driving circuit 50 for driving all XY-coordinate pixels. These circuits are composed of thin-film transistors (TFTs). Since the terminals of pad groups PDp need to be provided only for the inputs to the scanning line driving circuit 40 and signal line driving circuit 50, the number of these terminals is about 300.

In the manufacturing process, the array substrate requires a product inspection. Examples of the tester for inspecting the condition of the pixel region 30 include an electric tester and an electron beam tester (hereinafter referred to as “EB tester”). In an inspection using the electric tester, a charge is stored in an auxiliary capacitor of the pixel portion, and the stored charge is read out by a probe. In an inspection using the EB tester, a charge is stored in the auxiliary capacitor of the pixel portion, an electron beam is applied to the pixel portion, and emitted secondary electrons are detected.

In the case where the amorphous silicon type array substrate is inspected using the electric tester, about 3000 probes are necessary for the inspection. Since the probes are very expensive, the cost will be very high. In the case where the polysilicon type array substrate is inspected using the electric tester, about 300 probes are necessary for the inspection. Although the number of probes necessary is lower, the inspection has to be executed via the scanning line driving circuit 40 and signal line driving circuit 50, and the quality of the inspection will deteriorate. In addition, signal processing for the inspection becomes complex.

On the other hand, in the case where the amorphous silicon type array substrate is inspected using the EB tester, charges are stored in auxiliary capacitors of pixel portions via pad groups PDp from common probes, and thus the inspection using the EB tester is executed. In the case where the polysilicon type array substrate is inspected using the EB tester, charges can be stored in auxiliary capacitors of pixel portions via the scanning line driving circuit 40 and signal line driving circuit 50. However, since the pad groups PDp include various types of terminals for different signals, it is not possible to easily store charges using the common probes, as in the case of the amorphous silicon type array substrate.

The four examples, in which the amorphous silicon type array substrate and polysilicon type array substrate are inspected using the electric tester and EB tester, have been described. Next, a description is given of a method of inspecting the polysilicon type array substrate using the EB tester.

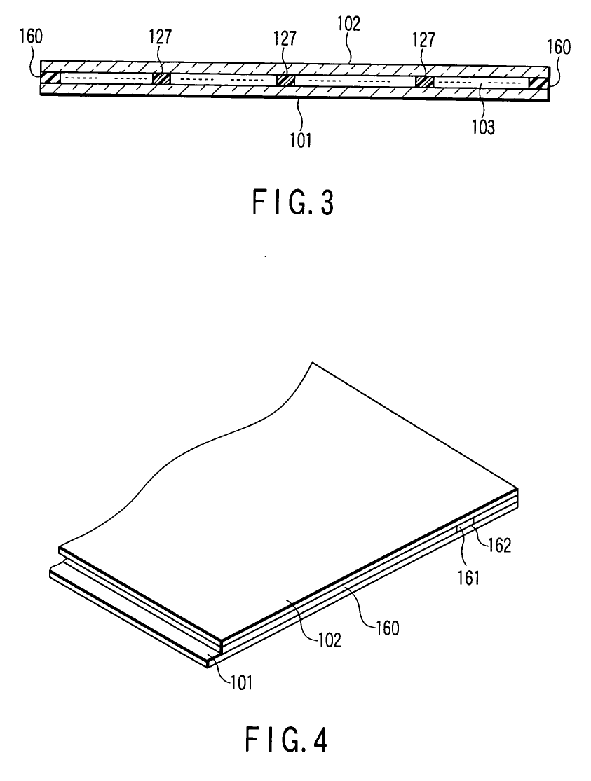

Referring to FIG. 3 and FIG. 4, a liquid crystal display panel including a polysilicon type array substrate is described. The polysilicon type array substrate is referred to as “array substrate 101” in the description below. As is shown in FIG. 3 and FIG. 4, the liquid crystal display panel includes an array substrate 101, an opposite substrate 102 that is arranged to be opposed to the array substrate with a predetermined gap therebetween, and a liquid crystal layer 103 that is held between both substrates. The predetermined gap is provided between the array substrate 101 and counter-substrate 102 by columnar spacers 127 that serve as spacers. A peripheral portion of the array substrate 101 and that of the opposite substrate 102 are bonded to each other by a seal member 160. A liquid crystal inlet 161, which is formed at a part of the seal member, is sealed by a sealant 162.

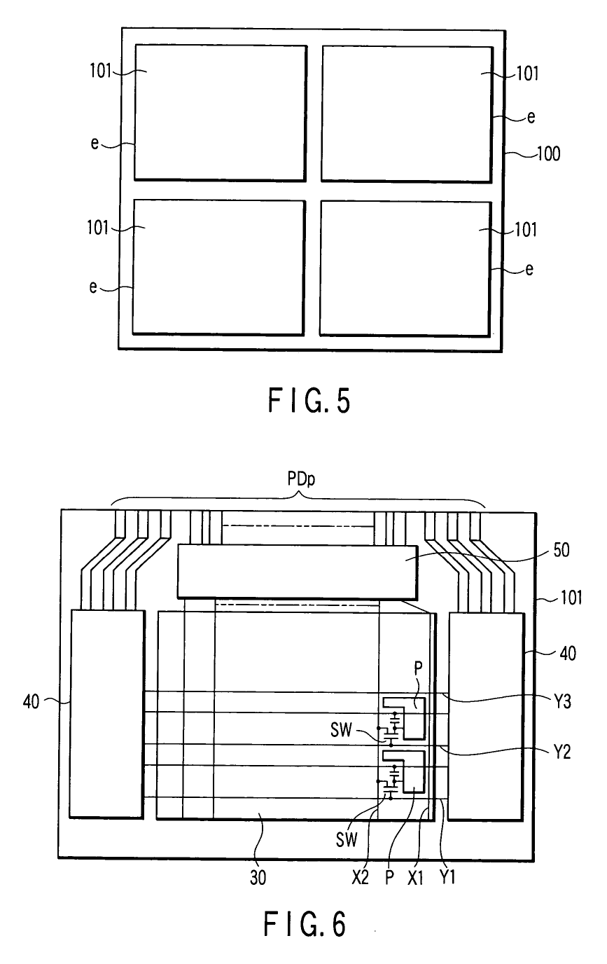

Referring now to FIG. 5, the array substrate 101 is described in detail. FIG. 5 shows a substrate (“mother substrate”) 100 that has a greater size than the array substrate. In the example shown in FIG. 5, the mother substrate 100 is used and four array substrates 101 are formed. In general, when array substrates 101 are formed, the mother substrate 100 is used. The structure of one of the array substrates 101 is described by way of example. The array substrate 101 includes a main region and a sub-region, which characterizes the present invention, as will be described later in detail.

As is shown in FIG. 6, a plurality of pixel electrodes P are arranged in a matrix in the pixel region 30 on the array substrate 101. The array substrate 101 includes, in addition to the pixel electrodes P, a plurality of scanning lines Y1, Y2, . . . (hereinafter, collectively represented by “Y”) that are disposed along rows of the pixel electrodes P, and a plurality of signal lines X1, X2, . . . (hereinafter, collectively represented by “X”) that are disposed along columns of the pixel electrodes P. Further, the array substrate 101 includes switching elements TFT SW that are arranged close to intersections between the scanning lines Y and signal lines X, a scanning line driving circuit 40 that drives the scanning lines, and a signal line driving circuit 50 that drives the signal lines.

Each TFT SW, when driven via the associated scanning line Y, applies a signal voltage from the associated signal line X to the associated pixel electrode P. The scanning line driving circuit 40 and signal line driving circuit 50 neighbor end portions of the array substrate 101 and are disposed on an outside area of the pixel region 30. The scanning line driving circuit 40 and signal line driving circuit 50 are composed of TFTs using polysilicon semiconductor films, like the TFT SW.

The array substrates 101 are arranged on one side of dicing lines on the mother substrate 100. Each of the array substrates 101 includes a regular pad group array PDp comprising a plurality of terminals that are connected to the scanning line driving circuit 40 and signal line driving circuit 50. The regular pad group array PDp is used to input different signals and to input/output inspection signals. The array substrates 101 are separated and cut out by dicing the mother substrate 100 along their edges e (FIG. 5).

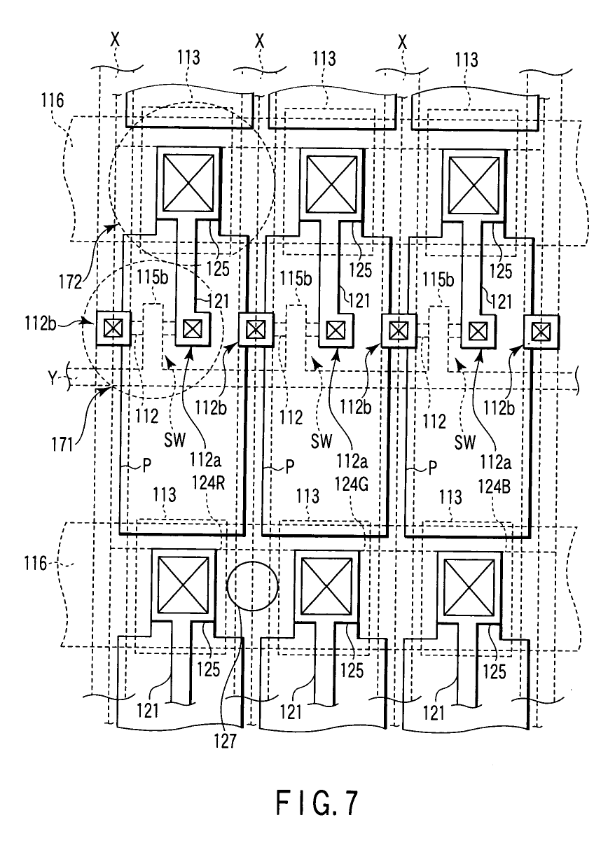

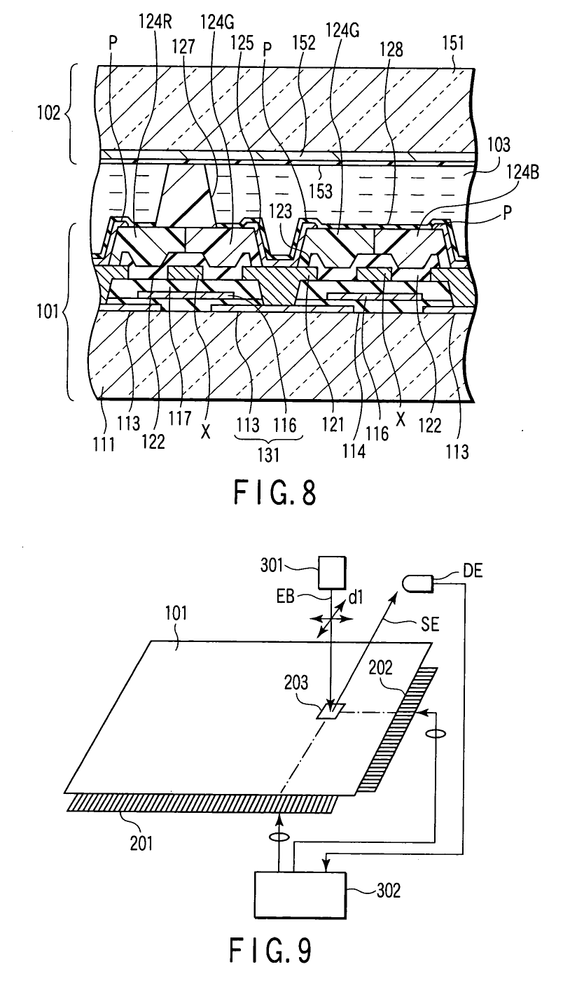

Referring to FIG. 7 and FIG. 8, a further description will be given by taking a part of the pixel region 30 shown in FIG. 6 by way of example. FIG. 7 is a plan view, and FIG. 8 is a cross-sectional view. The array substrate 101 includes a substrate 111 formed of a transparent insulating substrate (glass) (FIG. 8). In the pixel region 30, a plurality of signal lines X and a plurality of scanning lines Y are arranged in a matrix on the substrate 111. TFTs SW (see an encircled portion 171 in FIG. 7) are provided at each of intersections between the signal lines and scanning lines.

The TFT SW includes a semiconductor film 112 having source/drain regions 112a and 112b formed of polysilicon, and a gate electrode 115b that is an extension of the scanning line Y.

In addition, a plurality of striped auxiliary capacity lines 116, which constitute auxiliary capacity elements 131, are formed on the substrate 111, and the auxiliary capacity lines 116 extend in parallel to the scanning line Y. In those portions, the associated pixel electrodes P are formed (see an encircled portion 172 in FIG. 7, and FIG. 8).

To be more specific, the semiconductor films 112 and auxiliary capacity lower electrodes 113 are formed on the substrate 111, and a gate insulation film 114 is formed on the substrate including the semiconductor films and auxiliary capacity lower electrodes 113. Like the semiconductor films 112, the auxiliary capacity lower electrodes 113 are formed of polysilicon. The scanning lines Y, gate electrodes 115b and auxiliary capacity lines 116 are disposed on the gate insulation film 114. The auxiliary capacity lines 116 and auxiliary capacity lower electrodes 113 are disposed to be opposed to each other via the gate insulation film 114. An interlayer insulation film 117 is formed on the gate insulation film 114 that includes the scanning lines Y, gate electrodes 115b and auxiliary capacity lines 116.

Contract electrodes 121 and the signal lines X are formed on the interlayer insulation film 117. The contact electrodes 121 are connected to the source/drain regions 112a of the semiconductor films 112 and the pixel electrodes P via contact holes. The signal lines X are connected to the source/drain regions 112b of the semiconductor films via contact holes.

A protective insulation film 122 is formed over the contact electrodes 121, signal lines X and interlayer insulation film 117. Further, on the protective insulation film 122, striped green color layer 124G, striped red color layer 124R and striped blue color layer 124B are alternately arranged in a juxtaposed fashion, thereby forming a color filter.

Pixel electrodes P, which are formed of transparent electrically conductive films of ITO (Indium Tin Oxide), etc., are formed on the color layers 124G, 124R and 124B. Each of the pixel electrodes P is connected to the contact electrode 121 via a contact hole 125 that is formed in the color layer and protective insulation film 122. Peripheral parts of the pixel electrode P are laid over the auxiliary capacity lines 116 and signal lines X. The auxiliary capacity element 131, which is connected to the pixel electrode P, functions as an auxiliary capacitance for storing charge.

The columnar spacer 127 (see FIG. 7) is formed on the color layer 124R, 124G. Although all columnar spacers 127 are not shown, a plurality of columnar spacers 127 are formed on the respective color layers with a desired density. An alignment film 128 is formed on the color layers 124G, 124R and 124B and pixel electrodes P. The opposite substrate 102 includes a substrate 151 as a transparent insulating substrate. A opposite electrode 152 formed of a transparent material such as ITO, and an alignment film 153 are successively formed on the substrate 151.

With reference to FIG. 9, basic matters relating to the inspection method for the array substrate 101 using the EB tester are explained. The inspection is executed after forming the pixel electrode P on the substrate and before dicing the array substrates 101 out of the mother substrate 100 along the edges e.

A plurality of probes, which are connected to a signal generator and signal analyzer 302, are connected to the associated pads 201, 202. Driving signals, which are output from the signal generator and signal analyzer 302, are supplied to pixel portions 203 via the probes and pads 201, 202. After the driving signals are supplied to the pixel portions 203, electron beams EB, which are emitted from an electron beam source 301, are applied to the pixel portions. By the application, secondary electrons SE that represent voltages of the pixel portions 203 are emitted. The secondary electrons SE are detected by an electron detector DE. The secondary electrons SE are proportional to the voltage at a location from which the secondary electrons SE are emitted. In the inspection step, the pixel portions 203 of the array substrate 101 are electrically scanned by the driving signal from the signal generator and signal analyzer 302. The scanning is carried out in sync with the scanning of the electron beam EB over the surface of the array substrate 101, which is indicated by arrow a. Information of the secondary electrons, which are detected by the electron detector DE, is sent to the signal generator and signal analyzer 302 in order to analyze the pixel portions 203. In addition, the information of the secondary electrons, which is sent to the signal generator and signal analyzer 302, reflects the response performance of each pixel portion to driving signals that are supplied to terminals of the TFT of each pixel portion 203. Thereby, it becomes possible to check the voltages of the pixel electrodes P of each pixel section 203. In other words, if the pixel portions 203 have defects, the defects can be detected by the EB tester.

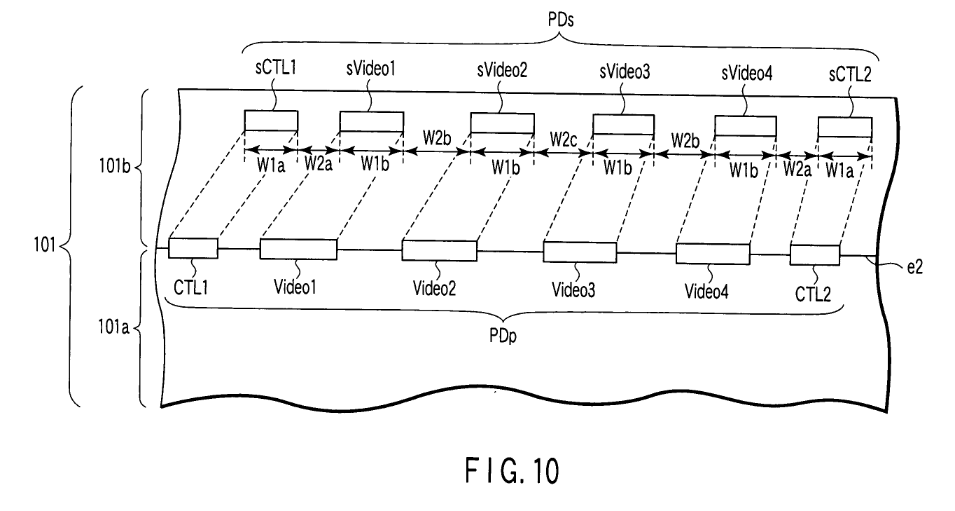

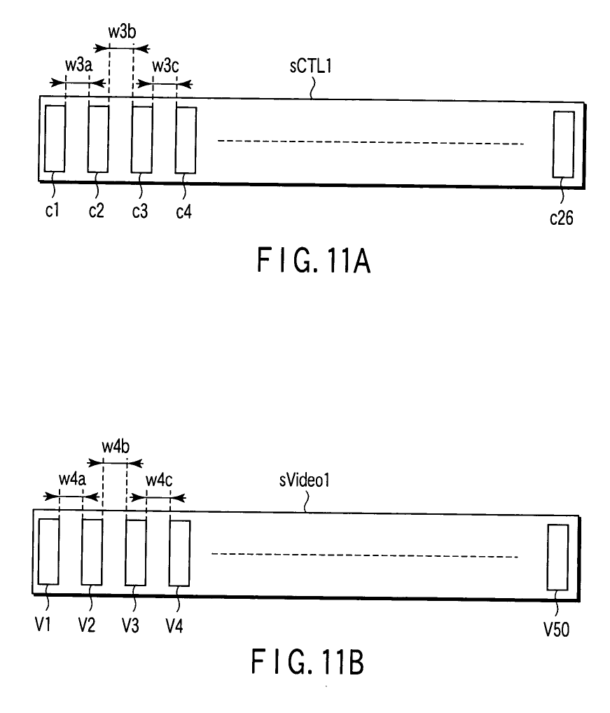

FIG. 10 is an enlarged view of a part of the array substrate 101, and shows an example of regular pad group array PDp that is provided in this part of the array substrate 101. The array substrate 101 includes an array substrate main region 101a and an array substrate sub-region 101b that is located outside the array substrate main region 101a. After the inspection, the array substrate sub-region 101b is taken away, for example, by drawing a scribe line along a dicing line e2.

The array PDp of regular pad groups in the array substrate main region 101a are connected to the scanning line driving circuit 40 and signal line driving circuit 50 shown in FIG. 6 via wiring lines. The scanning line driving circuit 40 and signal line driving circuit 50 are located on the lower side in the Figure, but depiction thereof is omitted here. The terminals of the array PDp of the regular pad groups are classified, as regular pad groups, into two control pad groups CTL1 and CTL2, and four video pad groups Video1, Video2, Video3 and Video4.

A clock signal, a start pulse signal, a high-level power and a low-level power are input to the control pad groups CTL1 and CTL2. Video signals are input to the video pad groups Video1, Video2, Video3 and Video4. Taking an XGA (extended Graphics Array) by way of example, the number of terminals of each of the control pad groups CTL1 and CTL2 is 26. The number of terminals of each of the video pad groups Video1, Video2, Video3 and Video4 is 50.

On the other hand, an array PDs of inspection pad groups (hereinafter referred to as “inspection pad group array”) is provided on the peripheral part of the array substrate sub-region 101b. The inspection pad group array PDs is connected to the regular pad group array PDp via wiring lines.

The structure of the inspection pad group array PDs is important in the present invention. The inspection pad group array PDs, like the regular pad group array PDp, include, as inspection pad groups, two sub-control pad groups sCTL1 and sCTL2, and four sub-video pad groups sVideo1, sVideo2, sVideo3 and sVideo4. The width w1a of each control pad group CTL1, CTL2 is 5.0 mm. The width w1b of each video pad group Video1, Video2, Video3, Video4 is 34.888 mm.

The intervals of the pad groups are as follows. The interval w2a between the sub-control pad group sCLT1 and the sub-video pad group sVideo1, as well as the interval w2a between the sub-control pad group sCLT2 and the sub-video pad group sVideo4, is 15.747 mm. The interval w2b between the sub-video pad group sVideo1 and the sub-video pad group sVideo2, as well as the interval w2b between the sub-video pad group sVideo3 and the sub-video pad group sVideo4, is 36.612 mm. The interval w2c between the sub-video pad group sVideo2 and the sub-video pad group sVideo3 is 36.33 mm. In this fashion, the inspection pad groups are disposed with predetermined intervals.

The number of terminals of each sub-control pad group sCTL1, sCTL2, like the control pad group CTL1, CTL2, is 26. The number of terminals of each sub-video pad group svideo1, sVideo2, sVideo3, sVideo4, like the video pad group Video1, Video2, Video3, Video4, is 50. The terminals that constitute these inspection pad groups are arranged in predetermined patterns.

As is shown in FIG. 11A and FIG. 11B, the intervals between terminals c1 to c26 of the sub-control pad group CTL1 are determined in accordance with a predetermined pattern. The interval w3a between the terminals c1 and c2, the interval w3b between the terminals c2 and c3 and the interval w3c between the terminals c3 and c4 are designed in accordance with the intervals of the terminals that constitute the probe groups. Similarly, the intervals of terminals V1 to V50 of the sub-video pad group sVideo1 are determined in accordance with a predetermined pattern. The interval w4a between the terminals V1 and V2, the interval w4b between the terminals V2 and V3 and the interval w4c between the terminals V3 and V4 are designed in accordance with the intervals of the terminals that constitute the probe groups.

An example of the structure of the inspection pad group array PDs has been described above. It should suffice if the intervals of the inspection pad groups and the intervals of the terminals of each inspection pad group are set at predetermined values, and are set in accordance with the intervals of the probe groups of a prescribed inspection apparatus for inspecting array substrate 101 the intervals of the probes of each probe group.

When the array substrate 101 with the above-described structure is to be inspected by the EB tester, the probes are connected to the terminals of the inspection pad group array PDs. A charge is accumulated in the pixel electrodes P and auxiliary capacity elements 131 of the pixel portions 203 via the probes. After the charge is accumulated, an electron beam is applied to each pixel portion 203, and secondary electrons emitted from each pixel portion are detected. Thereby, each pixel portion 203 is inspected as to whether or not it contains a defect. To be more specific, the electron beams are applied onto charged pixel electrodes P, and secondary electrons emitted from the pixel electrodes are detected and analyzed. Thereby, inspecting whether the pixel electrodes normally stores electric charge or not. The inspection, in this context, refers to inspections relating to the pixel electrodes, which inspect not only defects of the pixel electrodes P themselves, but also defects of the TFTs SW connected to the pixel electrodes, and defects of the auxiliary capacity elements 131 including the pixel electrodes.

According to the inspection method for the array substrate according to this embodiment, the array substrate 101 is inspected via the inspection pad group array PDs that is designed in advance in accordance with the arrangement of probes. Thus, even in the case where different kinds of liquid crystal display devices are to be inspected, the arrangement of the inspection pad group array PDs of the array substrate 101 is designed in advance in accordance with the arrangement of probes. Thereby, inspections can be executed using probes that are common to each kind. Even in the case where the arrangement of the regular pad group array PDp in the array substrate main region 101a is altered, the arrangement of the inspection pad group array PDs is forcibly formed to conform to the arrangement of the probes of the inspection apparatus. By devising combinations between the probes of the inspection apparatus and the array substrate, there is no need to use different probes for each kind. Thus, an array substrate for 12-inch devices and an array substrate for 15-inch devices, for instance, can be inspected with common probes. Thereby, the cost for the inspection apparatus can be reduced, and high-quality inspections can be executed.

The flexibility of the inspection apparatus can be enhanced, and the number of occasions in which design changes or modifications have to be made for the inspection apparatus can be reduced, and a rise in product prices of panels can be suppressed. Moreover, needless to say, out-flow of defective products of liquid crystal display devices can be suppressed.

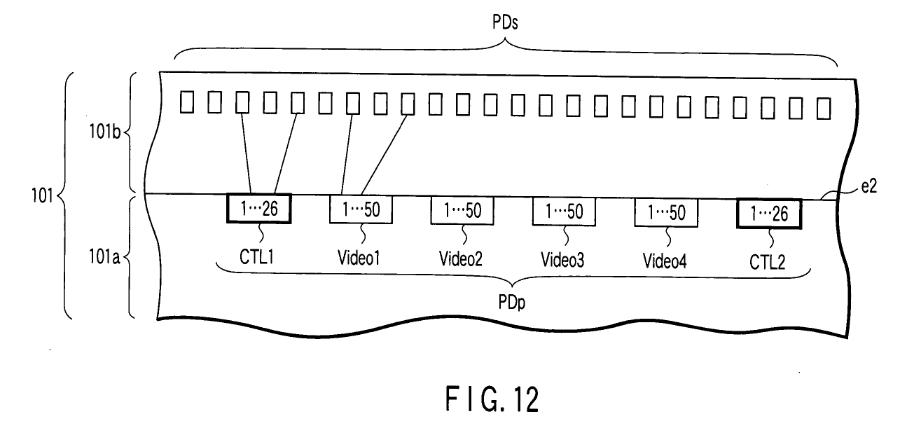

FIG. 12 illustrates an inspection method for an array substrate, according to another embodiment of the present invention. FIG. 12 shows, in enlarged scale, a part of an array substrate 101, and an example of a regular pad group array PDp and an inspection pad array PDsc that are provided in this part. After the inspection, an array substrate sub-region 101b is cut off by drawing, for example, a scribe line along a dicing line e2.

The inspection pad group array PDs is formed by arranging in advance a plurality of terminals in the array substrate sub-region 101b. The regular pad group array PDp comprises, as regular pad groups, two control pad groups CTL1 and CTL2, and four video pad groups Video1, Video2, Video3 and Video4. The number of terminals of the inspection pad array PDsc is greater than the number of terminals of the regular pad group array PDp.

The relationship in connection between the inspection pad array PDsc and the regular pad group array PDp is described. Each of the terminals of the regular pad group array PDp is connected to an arbitrary one of the terminals of the inspection pad array PDsc. Specifically, when each of the terminals of the regular pad group array PDp is to be connected to the terminals of the inspection pad array PDsc, each of the terminals of the regular pad group array PDp is connected to terminals of the inspection pad array PDsc in accordance with the arrangement of probes of a prescribed inspection apparatus.

Specifically, the arrangement pattern of the terminals of the inspection pad array PDsc, to which the terminals of the regular pad group array PDp are connected, is the same as the arrangement pattern of probes of the prescribed inspection apparatus.

Thereby, even in the case where an array substrate 101 with a different arrangement pattern of the regular pad group array PDp is to be inspected, the terminals of the inspection pad array PDsc, to which the probes of the inspection apparatus are put in contact, always agrees with the pattern of the probes. Thus, there is no need to use different probe groups for different kinds of substrates. In the meantime, not all the terminals of the inspection pad array PDsc are connected to the terminals of the regular pad group array PDp.

In the inspection method for the array substrate according to the present embodiment with the above-described structure, the array substrate 101 is inspected via the inspection pad array PDsc that is designed in advance in accordance with the arrangement of the probe group. The regular pad group array PDp includes a plurality of regular pad groups, and the terminals of the regular pad groups are connected to the terminals of the inspection pad array PDsc that is designed to agree with the arrangement of probes of the probe group. Thus, even in the case where different kinds of liquid crystal display devices are to be inspected, a common probe group can be used for each kind by designing in advance the arrangement of the terminals of the inspection pad array PDsc of the array substrate 101 in accordance with the arrangement of the probes.

The present invention is not limited to the above-described embodiments, and various modifications can be made without departing from the spirit of the invention. For example, the above-described array substrate 101 includes the scanning line driving circuit 40 and signal line driving circuit 50. However, it is possible to inspect an array substrate that does not include these driving circuits. When the array substrate is to be inspected, the inspection apparatus for use in the inspection is not limited to the EB tester, and it may be an electric tester.

What is claimed is:

1. A method for inspecting array substrates, which includes a first array substrate having at an end portion thereof first pads for electric power supply with a first array and first electrodes to be inspected, and a second array substrate having at an end portion thereof second pads for electric power supply with a second array different from the first array and second electrodes to be inspected, the method comprising:
connecting the first pads to terminals formed an array of inspection pad groups and disposed in a predetermined arrangement, bringing probes with an arrangement corresponding to the predetermined arrangement into contact with the terminals, and supplying electric power to the first electrodes via the probes, thereby inspecting whether the first electrodes of the first array substrate is defective or not; and
connecting the second pad to the terminals, bringing the probes, without changing the arrangement thereof, into contact with the terminals, and supplying electric power to the second electrodes via the probes, thereby inspecting whether the second electrodes of the second array substrate is defective or not.

2. A method for inspecting array substrates, each of which includes a substrate on which a plurality of scanning lines and a plurality of signal lines are disposed to intersect each other, pixel portions, which are formed on the substrate, arranged close to intersections of the scanning lines and the signal lines and includes switching elements and auxiliary capacitors, and a regular pad group that is provided to supply or output signals to the scanning lines and the signal lines, the method comprising:
forming in advance an inspection pad groups including terminals of an arrangement pattern corresponding to an arrangement pattern of a probe group of a prescribed inspection apparatus on the array substrates even in a case where different kinds of the array substrates, and connecting associated terminals of the regular pad group to the terminals of each of the inspection pad groups via wiring lines; and
bringing, at a time of an inspection, the probe group into contact with the terminals of the inspection pad groups of the array substrates of different kinds, without changing the arrangement pattern of the probe group of the inspection apparatus, thereby inspecting whether the array substrates are defective or not.

3. The method according to claim 2, wherein the inspection apparatus includes a plurality of probe groups which contain the probe group and are formed like the probe group, and
intervals of the plural inspection pad groups and intervals of a plurality of terminals that constitute each of the inspection pad groups are equal to intervals of a plurality of probe groups of the inspection apparatus and intervals of a plurality of probes that constitute each of the probe groups.

4. A method for inspecting array substrates, each of which includes a substrate on which a plurality of scanning lines and a plurality of signal lines are disposed to intersect each other, pixel portions, which are formed on the substrate, arranged close to intersections of the scanning lines and the signal lines and includes switching elements and auxiliary capacitors, and a regular pad group that is provided to supply or output signals to the scanning lines and the signal lines, the method comprising:
forming in advance inspection pad arrays including a plurality of terminals on the array substrates even in a case where different kinds of the array substrates, and connecting terminals of arrays of each of the regular pad group to the terminals of the inspection pad arrays in accordance with an arrangement of a probe group of a prescribed inspection apparatus; and
bringing, at a time of an inspection, the probe group into contact with the terminals of the inspection pad arrays of the array substrates of different kinds, without changing the arrangement pattern of the probe group of the inspection apparatus, thereby inspecting whether the array substrates are defective or not.
